(19) United States
(12) Patent Application Publication
(10) Pub. No.: US 2022/0256722 A1
(43) Pub. Date: Aug. 11, 2022

(54) ELECTRONIC DEVICE PACKAGE AND METHOD OF MANUFACTURING THE SAME

(71) Applicant: Advanced Semiconductor Engineering, Inc., Kaohsiung (TW)

(72) Inventor: Wei-Hao CHANG, Kaohsiung (TW)

(73) Assignee: Advanced Semiconductor Engineering, Inc., Kaohsiung (TW)

(21) Appl. No.: 17/169,226

(22) Filed: Feb. 5, 2021

(51) Int. Cl. H05K 5/02; H05K 5/06; H05K 7/14

(52) U.S. Cl. CPC H05K 5/0247; H05K 2203/1322; H05K 7/1438; H05K 5/065

(57) ABSTRACT

An electronic device package includes a substrate, at least one first electronic component and at least one electrical element. The substrate includes a first surface. The first surface comprises a plurality of electrical terminals including a first region and a second region, and a pitch of the electrical terminals of the first region is smaller than a pitch of the electrical terminals of the second region. The at least one first electronic component is electrically connected to the substrate and at least over the first region. The at least one electrical element is disposed above the first electronic component and farther from the substrate than the first electronic component. A number of the at least one electrical element under the first region is less than a number of the at least one electrical element under the second region.

### TECHNICAL FIELD

The present disclosure generally relates to an electronic device package and method of manufacturing the same, and more particularly to a three-dimensional (3D) stacking electronic device package and method of manufacturing the same.

### BACKGROUND

In a 3D stacking electronic device package, electronic components including active electronic components and/or passive electronic components are stacked to increase area utility. For example, a first electronic component may be flip chip bonded to a substrate, and a second electronic component may be vertically overlapping with the first electronic component. The first and second electronic components may be encapsulated by a molding layer. The second electronic component overlapping the first electronic component, however, would impede detection of the molding layer between the substrate and the first electronic component. Therefore, there is a desire for, for example, but not limited to, an electronic device package that would allow a detection of molding layer.

### SUMMARY

In some embodiments, an electronic device package includes a substrate, at least one first electronic component and at least one electrical element. The substrate includes a first surface. The first surface comprises a plurality of electrical terminals including a first region and a second region, and a pitch of the electrical terminals of the first region is smaller than a pitch of the electrical terminals of the second region. The at least one first electronic component is electrically connected to the substrate and at least over the first region. The at least one electrical element is disposed above the first electronic component and farther from the substrate than the first electronic component. A number of the at least one electrical element under the first region is less than a number of the at least one electrical element under the second region.

In some embodiments, an electronic device package includes a substrate, at least one first electronic component and at least one electrical element. The substrate includes a first surface. The first surface comprises a plurality of electrical terminals including a first region and a second region, and a pitch of the electrical terminals of the first region is smaller than a pitch of the electrical terminals of the second region. The at least one first electronic component is electrically connected to the substrate and at least over the first region. The at least one electrical element is disposed above the first electronic component and farther from the substrate than the first electronic component. An area of the at least one electrical element under the first region projected on the first surface in a direction substantially perpendicular to the first surface is less than an area of the at least one electrical element under the second region projected on the first surface in the direction.

In some embodiments, an electronic device package includes a substrate, at least one first electronic component and at least one electrical element. The substrate includes a first surface. The first surface comprises a plurality of electrical terminals including a first region and a second region, and a pitch of the electrical terminals of the first region is smaller than a pitch of the electrical terminals of the second region. The at least one first electronic component is electrically connected to the substrate and at least over the first region. The at least one electrical element is disposed above the first electronic component and farther from the substrate than the first electronic component. A defect detectability in and/or under the first region is higher than a defect detectability in and/or under the second region.

### BRIEF DESCRIPTION OF THE DRAWINGS

Aspects of the present disclosure are best understood from the following detailed description when read with the accompanying figures. It is noted that various features may not be drawn to scale, and the dimensions of the various features may be arbitrarily increased or reduced for clarity of discussion.

FIG. 1 is a schematic top view of an electronic device package in accordance with some embodiments of the present disclosure.

FIG. 1A is a schematic cross-sectional view of an electronic device package along a line A-A′ in accordance with some embodiments of the present disclosure.

FIG. 2 is a schematic top view of an electronic device package in accordance with some embodiments of the present disclosure.

FIG. 2A is a schematic cross-sectional view of an electronic device package along a line B-B′ in accordance with some embodiments of the present disclosure.

FIG. 3 is a schematic top view of an electronic device package in accordance with some embodiments of the present disclosure.

FIG. 3A is a schematic cross-sectional view of an electronic device package along a line C-C′ in accordance with some embodiments of the present disclosure.

FIG. 4A, FIG. 4B, FIG. 4C, FIG. 4D, FIG. 4E. FIG. 4F, FIG. 4G and FIG. 4H illustrate operations of manufacturing an electronic device package in accordance with some embodiments of the present disclosure.

FIG. 5 is a schematic top view of an electronic device package in accordance with some embodiments of the present disclosure.

FIG. 6A, FIG. 6B, FIG. 6C and FIG. 6D illustrate operations of manufacturing an electronic device package in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Some embodiments, or examples, illustrated in the figures are disclosed below using specific language. It will nevertheless be understood that the embodiments and examples are not intended to be limiting. Any alterations and modifications of some of the disclosed embodiments, and any further applications of the principles disclosed in this document, as would normally occur to one of ordinary skill in the pertinent art, fall within the scope of this disclosure.

Further, it is understood that several processing steps (e.g., operations) and/or features of a device may be briefly described. Also, additional processing steps and/or features can be added, and certain of the processing steps and/or features described herein can be removed or changed while implementing the methods described herein or while using the systems and devices described herein. Thus, the following description should be understood to represent examples, and are not intended to suggest that one or more steps or features are required for every implementation. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

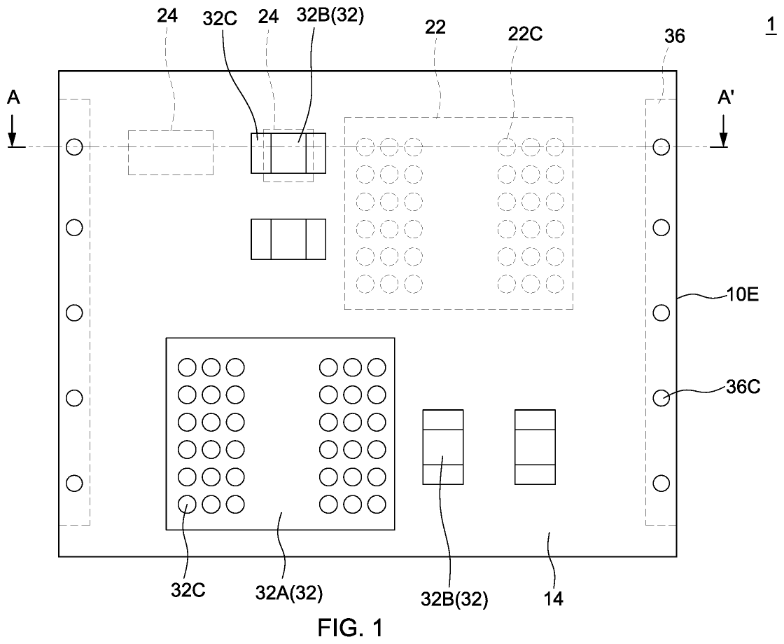

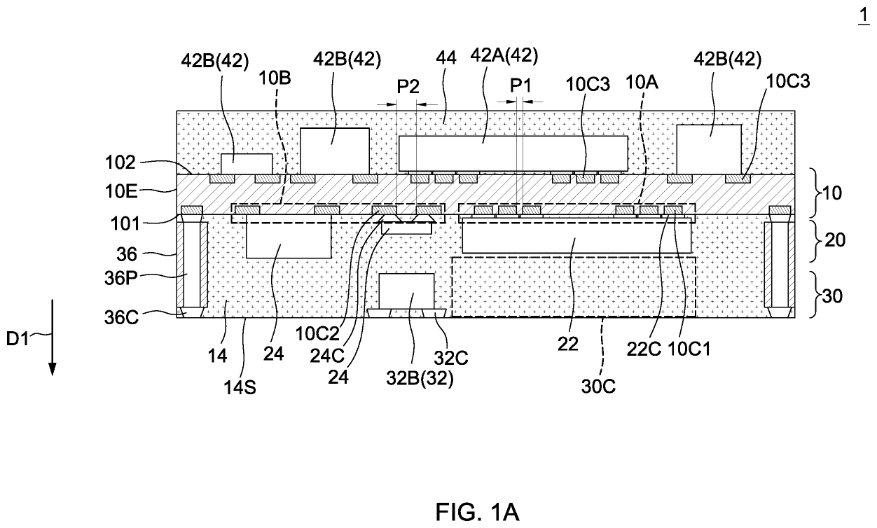

FIG. 1 is a schematic top view of an electronic device package 1 in accordance with some embodiments of the present disclosure, and FIG. 1A is a schematic cross-sectional view of an electronic device package 1 along a line A-A′ in accordance with some embodiments of the present disclosure. As shown in FIG. 1 and FIG. 1A, the electronic device package 1 includes a substrate 10, a first component layer 20 and a second component layer 30. The substrate 10 includes a first surface 101, and a second surface 102 opposite to the first surface 101. The substrate 10 may include an interposer, a circuit layer such as a redistribution layer (RDL) or another type of substrate that includes embedded circuitry between the first surface 101 and the second surface 102. The first surface 101 of the substrate 10 includes a first region 10A and a second region 10B. The device area density of the first region 10A is greater than the device area density of the second region 10B. As used herein, the device area density may be referred to a ratio of an area of device(s) disposed in a region of the substrate to an overall area of the region. The device may be referred to an electronic component such as an active electronic device including a semiconductor die, a passive electronic device such as a capacitor, a resistor or an inductor, an electrical terminal such as a pad or a UBM. In some embodiments, the first region 10A is adjacent to a corner of the substrate 20.

The first surface 101 may include a plurality of electrical terminals including a first region 10A and a second region 10B. In some embodiments, the substrate 10 further comprises a plurality of first electrical terminals 10C1 in the first region 10A, and a plurality of second electrical terminals 10C2 in the second region 10B. The first electrical terminals 10C1 and the second electrical terminals 10C2 are electrically connected to the embedded circuitry of the substrate 10. By way of example, the first electrical terminals 10C1 and the second electrical terminals 10C2 may be pads such as bonding pads disposed in the first region 10A and the second region 10B, respectively. In some embodiments, an electrical terminal density of the first electrical terminals 10C1 is greater than an electrical terminal density of the second electrical terminals 10C2. As used herein, the electrical terminal density may be referred to a ratio of an area of the electrical terminals disposed in a region of the substrate to an overall area of the region. In this embodiment, the ratio of the area of the first electrical terminals 10C1 in the first region 10A is greater than the ratio of the area of the second electrical terminals 10C2 in the first region 10B. In some embodiments, a pitch P1 of the first electrical terminals 10C1 of the first region 10A is smaller than a pitch P2 of the second electrical terminals 10C2 of the second region 10B.

The first component layer 20 is disposed over the first surface 101 of the substrate 10. The first component layer 20 comprises a first electronic component 22 electrically connected to the substrate 10 and at least over the first region 10A. In some embodiments, the first electronic component 22 includes an active electronic device such as a semiconductor die. The first electronic component 22 may further includes a plurality of conductive structures 22C electrically connected to the first electrical terminals 10C1 of the first region 10A. In some embodiments, the first component layer 20 may further include a second electronic component 24 over the second region 10B. The electrical terminal density of the first electronic component 22 is greater than the electrical terminal density of the second electronic component 24. For example, the second electronic component 24 includes a passive electronic component such as a resistor, a capacitor, an inductor or a combination thereof. The second electronic component 24 may further include a plurality of conductive structures 24C electrically connected to the second electrical terminals 10C2 of the second region 10B. By way of example, the conductive structures 22C and 24C may include conductive studs, conductive pillars, solder bumps, solder pastes, solder balls or a combination thereof.

The second component layer 30 is disposed over the first component layer 20 and farther from the substrate 10 than the first component layer 20. In other words, the first component layer 30 is disposed between the substrate 10 and the second component layer 30. The second component layer 30 includes at least one electrical element 32 having a plurality of input/output (I/O) terminals 32C away from the first component layer 20. In some embodiments, the at least one electrical element 32 may include an active electrical element 32A and/or a passive electrical element 32B. The at least one electrical element 32 is without overlapping the first electronic component 22 in a direction D1 substantially perpendicular to the first surface 101 and under the first surface 101. The at least one electrical element 32 may overlap the second electronic component 24 in the direction D1. In some embodiments, the second component layer 30 may include a plurality of electrical elements 32, and an electrical element 32 of the electrical elements 32 proximal to the first electronic component 22 is without overlapping the first electronic component 22 in the direction D1. That is, all electrical elements 32 are without overlapping the first electronic component 22 in the direction D1. In some embodiments, a number of the electrical element 32 under the first region 10A is less than a number of the electrical element 32 under the second region 10B. In some embodiments, an area of the electrical element 32 under the first region 10A is less than an area of the at least one electrical element 32 under the second region 10B.

The electronic device package 1 may further include a first encapsulation layer 14 over the first region 10A and the second region 10B and encapsulating the first component layer 20 and the second component layer 30. By way of examples, the first encapsulation layer 14 encapsulates the first electronic component 22 and the second electronic component 24 of the first component layer 20, and the at least one electrical element 32 of the second component layer 30. In some embodiments, a surface of the first encapsulation layer 14 and a surface of the second component layer 30 are substantially coplanar. The I/O terminals 32C of the electrical element 32 are exposed from the first encapsulation layer 14 to electrically connect to an external electrical component (not shown) such as a printed circuit board (PCB). The first encapsulation layer 14 may include molding compound such as epoxy-based material (e.g. FR4), resin-based material (e.g. Bismaleimide-Triazine (BT), Polypropylene (PP)) or other suitable materials.

The electronic device package 1 may further include a plurality of electrical connection elements 36 electrically connected to the substrate 10, and extending through the first component layer 20 and the second component layer 30. In some embodiments, the electrical connection elements 36 may include conductive pillars 36P such as copper pillars, and electrical terminals 36C partially embedded in the first encapsulation layer 14 and exposed from an outer surface 14S of the first encapsulation layer 14 to electrically connect to the external electrical component. The electrical connection elements 36 are not disposed over the first region 10A. In some embodiments, the electrical connection elements 36 may be disposed over the second region 10B, or over other region of the substrate 10. By way of example, the electrical connection elements 36 are disposed to at least one edge 10E of the substrate 10.

The defect detectability in and/or under the first region 10A is higher than the defect detectability in and/or under the second region 10B. As used herein, the defect detectability may be referred to the ability of detecting defect. A higher defect detectability means the defect is easier to be detected, and a lower defect detectability means the defect is more difficult to be detected. By way of example, the defect detectability may include void detectability, i.e., the ability of detecting void defect. In the proximity of the high device density first region 10A, defects such as void defects tends to appear, and thus a higher defect detectability is required. In the proximity of the low device density second region 10B, defects are less likely to occur, and thus the requirement of defect detectability near the second region 10B may not be as important as the requirement of defect detectability near the first region 10A.

In some embodiments, the second component layer 30 defines a clearance region 30C over the first region 10A. The clearance region 30C overlaps the first electronic component 22 in the direction D1. As used herein, the clearance region 30C of the second component layer 30 may be referred to a region that allows detecting the first encapsulation layer 14 between the first electronic component 22 and the first region 10A of the substrate 10 to check if voids defects of the first encapsulation layer 14 appear. In some embodiments, the first encapsulation layer 14 is disposed in the clearance region 30C, i.e., the clearance region 30C may be a portion of the first encapsulation layer 14 in the absence of other electronic components. In some other embodiments, the clearance region 30C of the second component layer 30 may be a recessed region of the first encapsulation layer 14. The clearance region 30C allows acoustic wave to pass through such that voids of the first encapsulation layer 14 in a tiny gap between the substrate 10 and the first electronic component 22 can be detected.

In some embodiments, the substrate 10 may further include a plurality of third electrical terminals 10C3 exposed from the second surface 102, and electrically connected to the embedded circuitry of the substrate 10. The electronic device package 1 may further include at least one third electronic component 42 disposed over the second surface 102 of the substrate 10, and electrically connected to the substrate 10 through the third electrical terminals. For example, the at least one third electronic component 42 includes one or more active electronic components 42A such as application specific integrated circuit (ASIC) dies, memory dies or a combination thereof, and one or more passive electronic component 42B such as resistors, capacitors, inductors or a combination thereof. The electronic device package 1 may further include a second encapsulation layer 44 over the second surface 102 of the substrate 10, and encapsulating the at least one third electronic component 42. The second encapsulation layer 44 may include molding compound such as epoxy-based material (e.g. FR4), resin-based material (e.g. Bismaleimide-Triazine (BT), Polypropylene (PP)) or other suitable materials.

The stack of the first component layer 20 and the second component layer 30 increases the device integration of the electronic component device package 1. The clearance region 30C of the second component layer 30 allows to perform a detection such as a scan acoustic tomography (SAT) detection to detect mold void in the first encapsulation layer 14, particularly in the tiny space between the first electronic component 22 and the substrate 10 where mold voids tend to occur. Accordingly, the reliability of the electronic component device package 1 can be improved.

The electronic device packages and manufacturing methods of the present disclosure are not limited to the above-described embodiments, and may be implemented according to other embodiments. To streamline the description and for the convenience of comparison between various embodiments of the present disclosure, similar components of the following embodiments are marked with same numerals, and may not be redundantly described.

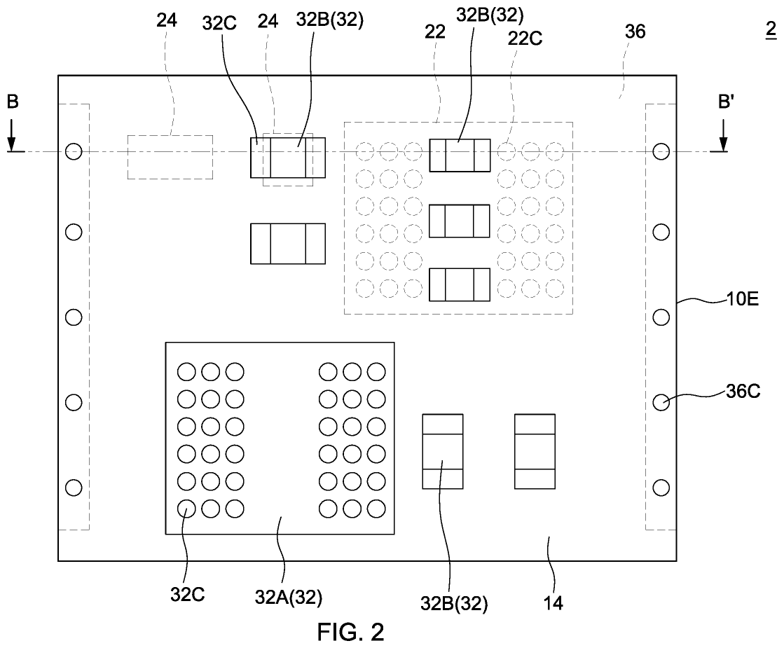

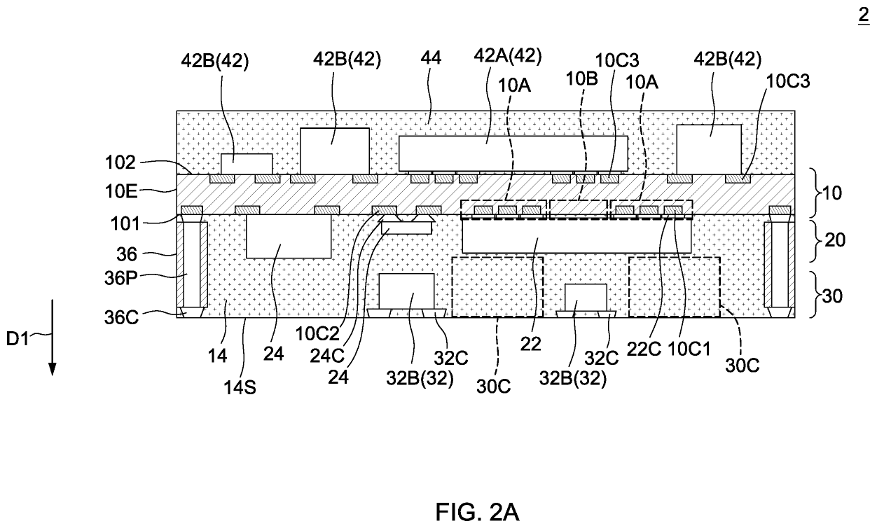

FIG. 2 is a schematic top view of an electronic device package 2 in accordance with some embodiments of the present disclosure, and FIG. 2A is a schematic cross-sectional view of an electronic device package 2 along a line B-B′ in accordance with some embodiments of the present disclosure. As shown in FIG. 2 and FIG. 2A, in contrast to the electronic device package 1, the substrate 10 includes a plurality of first electrical terminals 10C1 in the first region 10A, and the second region 10B is free of electrical terminal. By way of example, the second region 10B may be disposed between two first regions 10A, or surrounded by a first region 10A. The first electronic component 22 may be disposed over both the first region 10A and the second region 10B. The first electronic component 22 further comprises a plurality of conductive structures 22C electrically connected to the first electrical terminals 10C1 of the first region 10, and the second region 10B is free of conductive structure of the first electronic component 22 and electrical terminals of the substrate 10. The second component layer 30 defines one or more clearance regions 30C over the first region 10A. The at least one electrical element 32 may overlap the first electronic component 22 in the direction D, but may be without overlapping the clearance regions 30C in the direction D. The device area density of the first region 10A is greater than the device area density of the second region 10B. By way of example, there are the first electrical terminals 10C1 in the first region 10A, and there are no electrical terminals in the second region 10B. Accordingly, the electrical terminal density of the first region 10A is greater than zero, and the electrical terminal density of the second region 10B is zero.

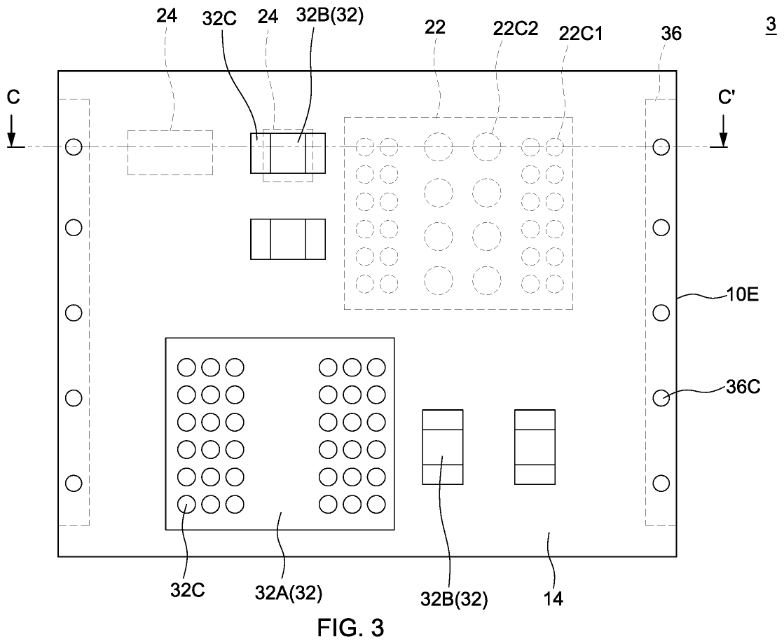

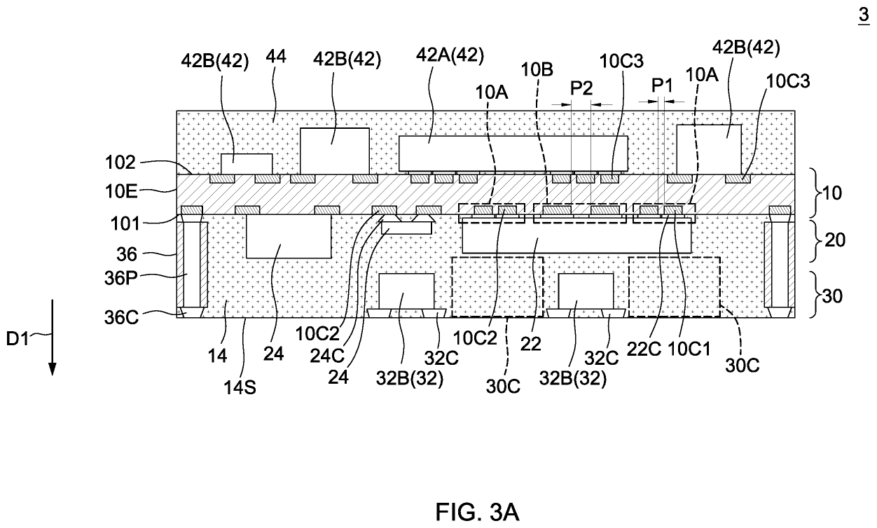

FIG. 3 is a schematic top view of an electronic device package 3 in accordance with some embodiments of the present disclosure, and FIG. 3A is a schematic cross-sectional view of an electronic device package 3 along a line C-C′ in accordance with some embodiments of the present disclosure. As shown in FIG. 3 and FIG. 3A, in contrast to the electronic device package 2, the substrate 10 includes a plurality of first electrical terminals 10C1 in the first region 10A, and a plurality of second electrical terminals 10C2 in the second region 10B. The first electronic component 22 may be disposed over both the first region 10A and the second region 10B. The first electronic component 22 further includes a plurality of first conductive structures 22C1 electrically connected to the first electrical terminals 10C1 of the first region 10A, and a plurality of second conductive structures 22C2 electrically connected to the second electrical terminals 10C2 of the second region 10B. The device area density of the first region 10A is greater than the device area density of the second region 10B. By way of example, there are the first electrical terminals 10C1 in the first region 10A, and the second electrical terminals 10C2 in the second region 10B. The density of the first electrical terminals 10C1 is greater than the density of the second electrical terminals 10C2. Accordingly, the electrical terminal density of the first region 10A is greater than the electrical terminal density of the second region 10B.

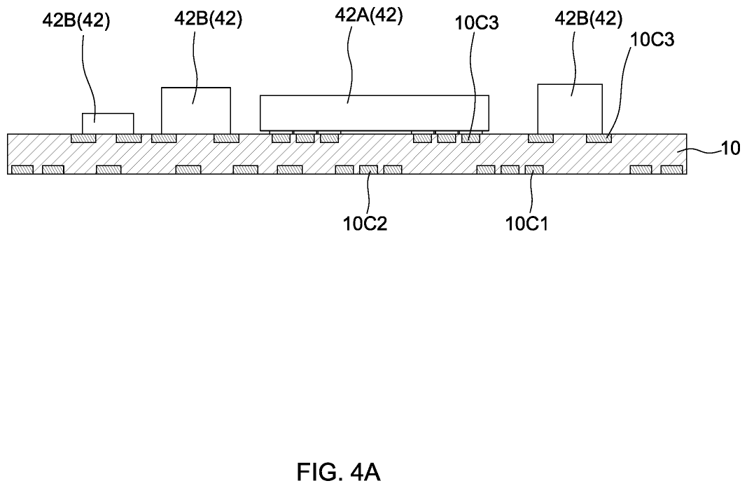

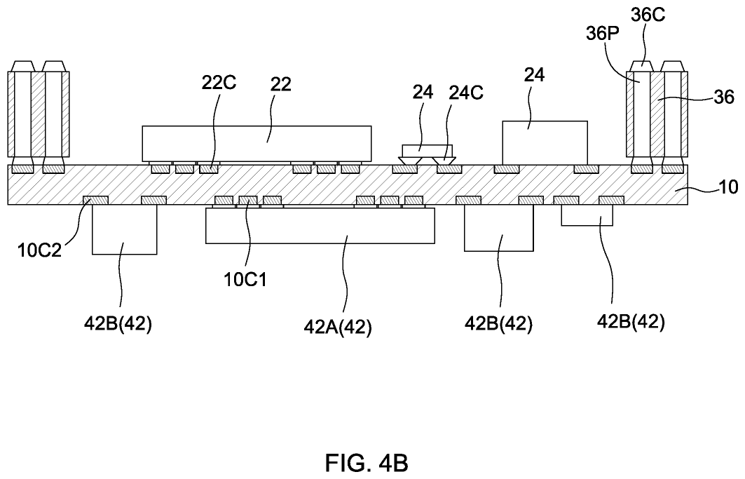

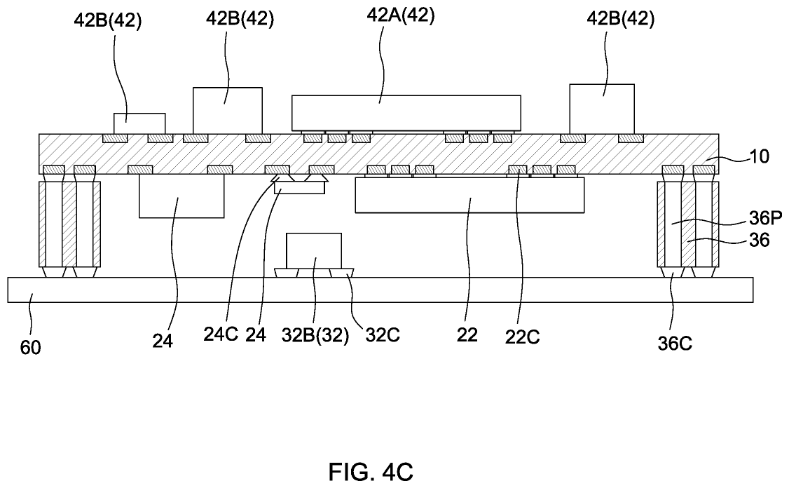

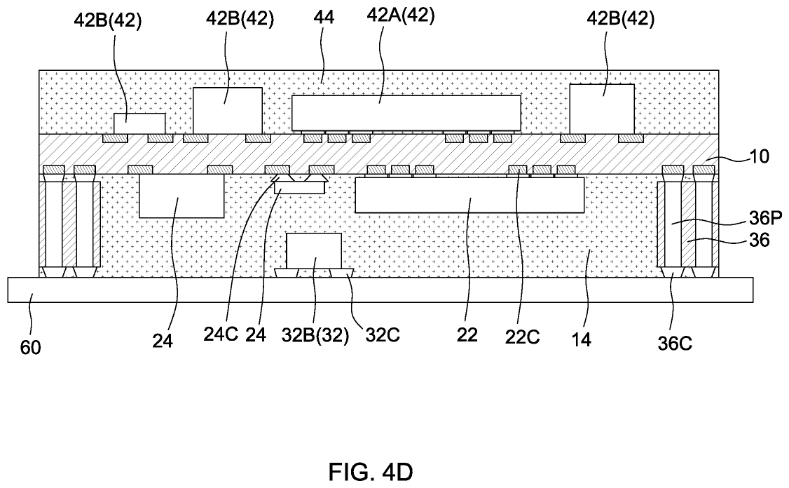

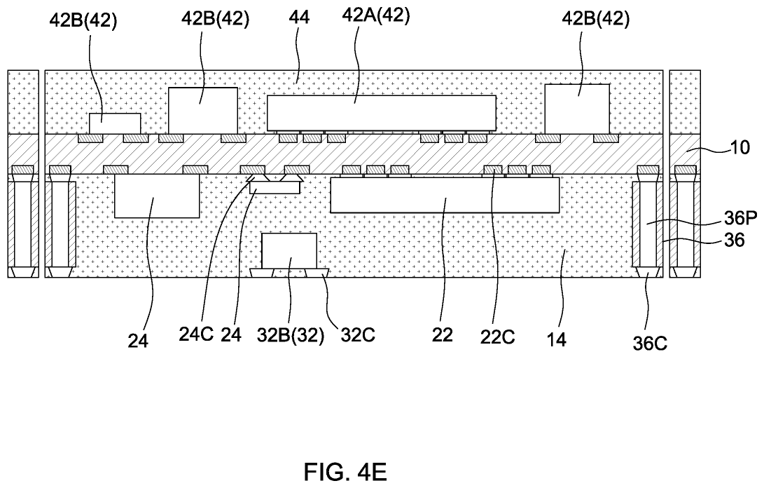

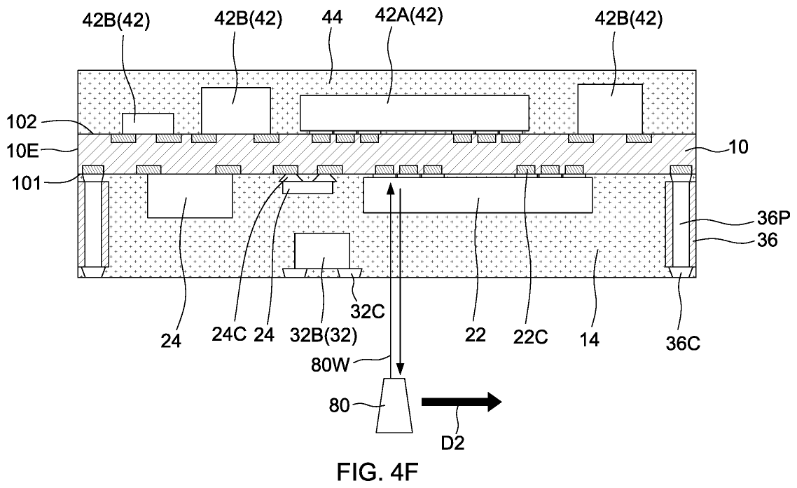

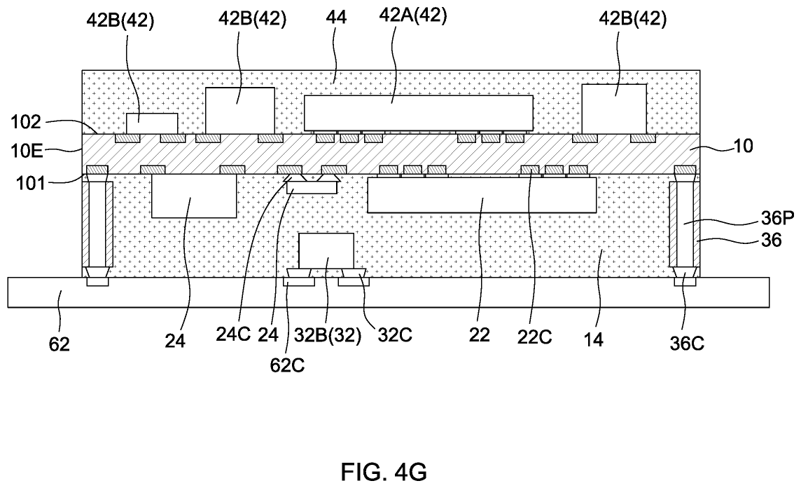

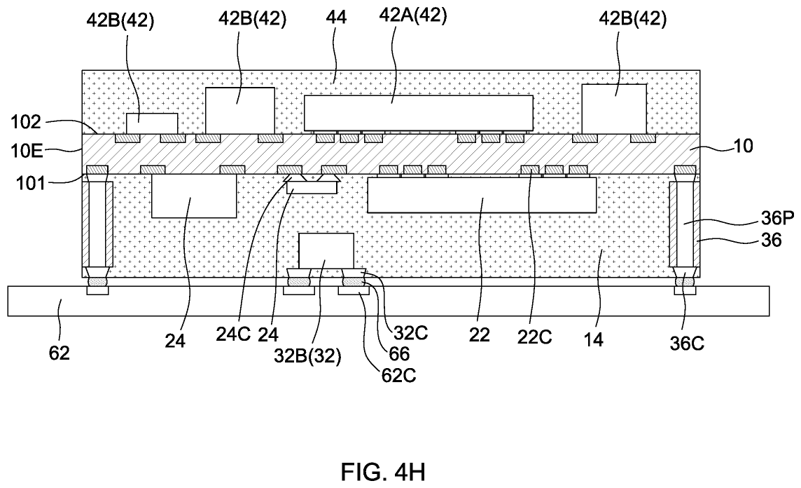

FIG. 4A, FIG. 4B, FIG. 4C, FIG. 4D, FIG. 4E. FIG. 4F, FIG. 4G and FIG. 4H illustrate operations of manufacturing an electronic device package in accordance with some embodiments of the present disclosure. As shown in FIG. 4A, a substrate 10 is provided. The substrate 10 includes a first surface 101, and a second surface 102 opposite to the first surface 101. The first surface 101 has a first region 10A and a second region 10B. The device area density of the first region 10A is greater than the device area density of the second region 10B. In some embodiments, the substrate 10 comprises a plurality of first electrical terminals 10C1 in the first region 10A, and a plurality of second electrical terminals 10C2 in the second region 10B, and the electrical terminal density of the first electrical terminals 10C1 is greater than the electrical terminal density of the second electrical terminals 10C2. In some other embodiments, the substrate 10 includes a plurality of first electrical terminals 10C1 in the first region 10A, and the second region 10B is free of electrical terminal. In some embodiments, electronic components (also referred to as third electronic components) 42 may be mounted on the second surface 102 of the substrate 10, and electrically connected to the third electrical terminals 10C3 of the substrate 10.

As shown in FIG. 4B, first electronic component(s) 22 may be bounded to the first region 10A. By way of example, the first electronic component(s) 22 may be bounded to the first electrical terminals 10C1 of the substrate 10 through conductive structures 22C. Second electronic component(s) 24 may be bonded to the second region 10B. For example, the second electronic component(s) 24 may be bonded to the second electrical terminals 10C2 of the substrate 10 through conductive structures 24C. In some embodiments, a plurality of electrical connection elements 36 may be mounted on the first surface 101 of the substrate 10.

As shown in FIG. 4C, an electrical element 32 is suspended over the surface of the substrate without overlapping the first region 10A. In some embodiments, the electrical element 32 is temporarily supported by a carrier 60. The carrier 60 may be temporarily adhered to the electrical connection elements 36, and the location of the electrical element 32 supported by the carrier 60 is selected such that the electrical element 32 is without overlapping the first region 10A.

As shown in FIG. 4D, a first encapsulation layer 14 is formed on the first surface 101 of the substrate 10 to encapsulate the first electronic component 22 and the electrical element 32. In some embodiments, a second encapsulation layer 44 is formed on the second surface 102 of the substrate 10 to encapsulate the third electronic components 42. In some embodiments, the first encapsulation layer 14 and the second encapsulation layer 44 may include the same molding compound, and formed by the same molding process. Because the electrical element 32 suspended over the first surface 101 of the substrate 10 is without overlapping the first region 10A, a clearance region 30C is formed over the first region 10A.

As shown in FIG. 4E, the carrier 60 is released from the first encapsulation layer 14 and the electrical connection elements 36. Subsequently, a singulation process is performed to form a plurality of electronic device packages 1, 2 or 3 as illustrated in FIG. 1, 2 or 3. As shown in FIG. 4F, a detection is performed through the clearance region 30C and the first electronic component 22 to detect the first encapsulation layer 14 between the first electronic component 22 and the first region 10A of the substrate 10. In some embodiments, the detection comprises an acoustic detection such as a can acoustic tomography (SAT) detection. In the SAT detection, an acoustic detection apparatus 80 can be used to transmit acoustic wave 80W through the clearance region 30C and the first electronic component 22 along a scanning direction D2 to detect whether mold voids exist between the tiny space between the first electronic component 22 and the first region 10A. The reflected acoustic wave 80W can be sensed and analyzed to confirm whether mold voids exist between the tiny space between the first electronic component 22 and the first region 10A or not. In some embodiments, the clearance region 30C may be a portion of the first encapsulation layer 14 in which electronic component or other structures that impedes traveling of the acoustic wave 80W is avoided. Accordingly, the detection can be performed.

As shown in FIG. 4G, the electronic device package may be bonded to an external electrical component 62 such as a printed circuit board (PCB). The I/O terminals 32C of the electrical element 32 and/or the electrical terminals 36C of the electrical connection elements 36 may be electrically connected to pads 62C of the external electrical component 62. In some alternative embodiments, the electronic device package may be bonded to the external electrical component 62 through electrical connectors 66 such as solder paste, solder paste or the like as illustrated in FIG. 4H. The electrical connectors 66 may be disposed between the first encapsulation layer 14 and the external electrical component 62, and a space gap may exist therebetween.

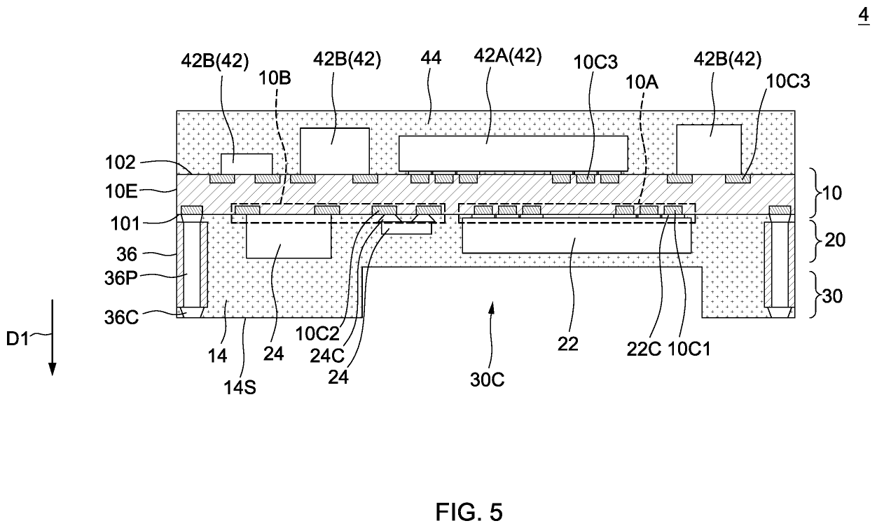

FIG. 5 is a schematic top view of an electronic device package 4 in accordance with some embodiments of the present disclosure. As shown in FIG. 5, in contrast to the electronic device package 1, the clearance region 30C is an empty space defined by the second component layer 30. The clearance region 30C is a recessed region of the first encapsulation layer 14. The clearance region 30C allows acoustic wave to pass through such that voids of the first encapsulation layer 14 in a tiny gap between the substrate 10 and the first electronic component 22 can be detected. In some embodiments, other electrical components may be disposed in the clearance region 30C after the detection process to increases the device integration of the electronic component device package 4.

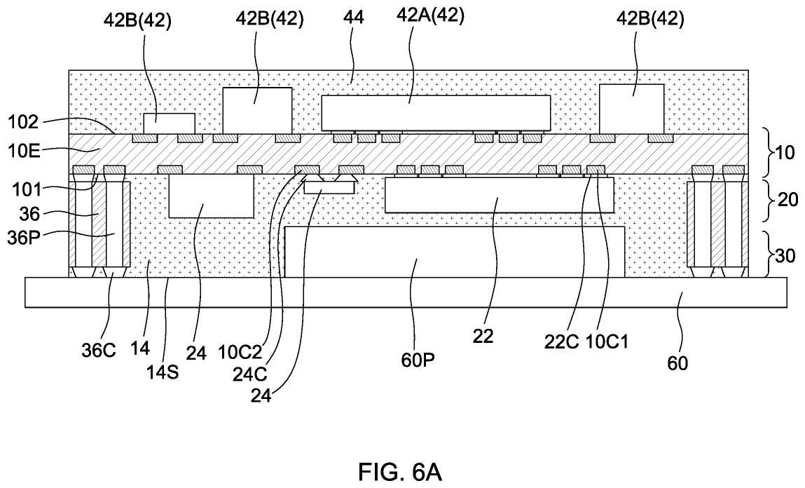

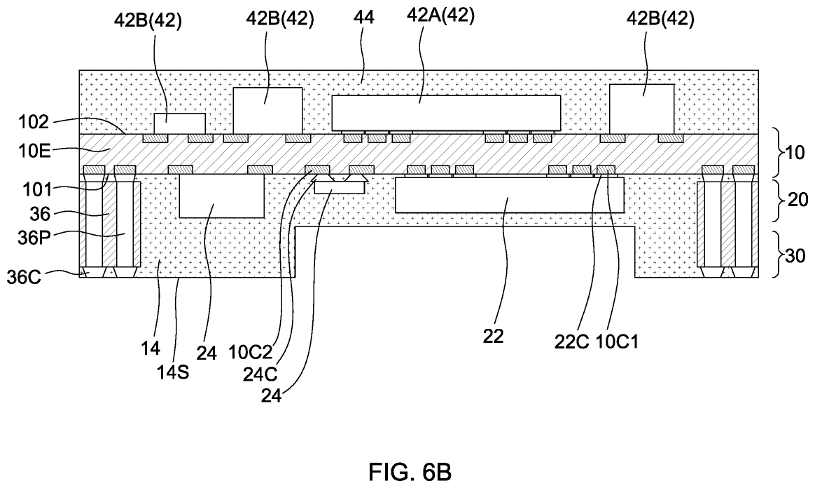

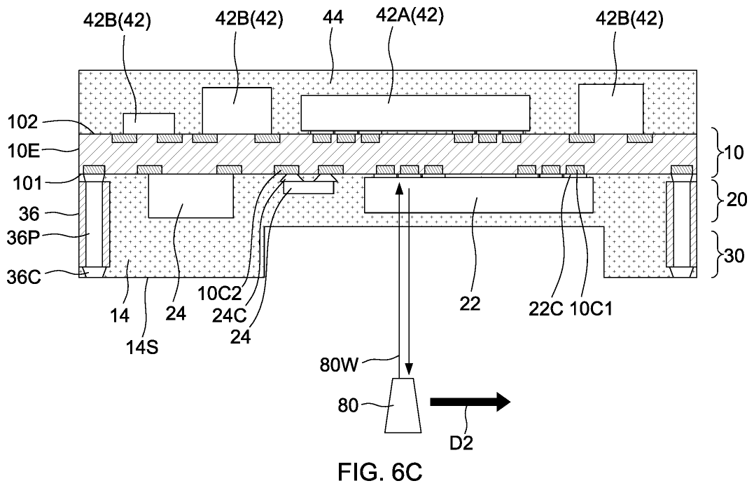

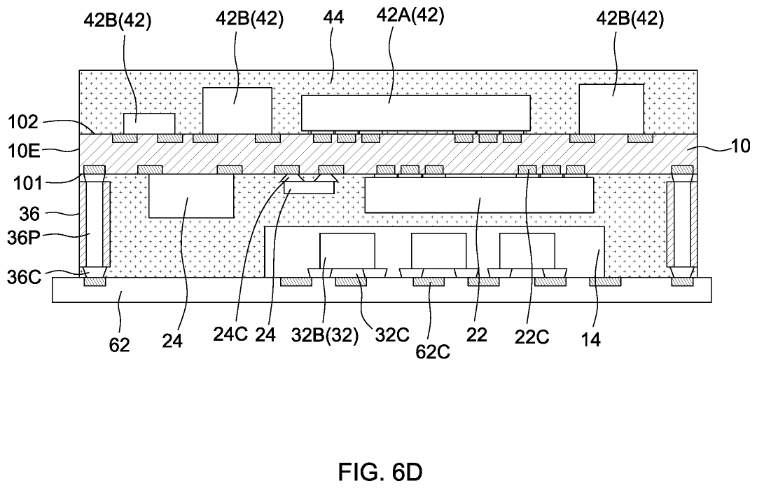

FIG. 6A, FIG. 6B, FIG. 6C and FIG. 6D illustrate operations of manufacturing an electronic device package in accordance with some embodiments of the present disclosure. As shown in FIG. 6A, a carrier 60 including a protrusion portion 60P is used to temporarily support the electrical connection elements 36. Subsequently, a molding process is performed to form a first encapsulation layer 14 and the second encapsulation layer 44. By virtue of the protrusion portion 60P, a clearance region 30C formed by a recess of the first encapsulation layer 14 can be formed subsequent to the carrier 60 is removed as shown in FIG. 6B.

As shown in FIG. 6C, a detection such as a SAT detection is performed through the clearance region 30C and the first electronic component 22 to detect the first encapsulation layer 14 between the first electronic component 22 and the first region 10A of the substrate 10. In some embodiments, the clearance region 30C being a recess portion of the first encapsulation layer 14 does not impede traveling of the acoustic wave, and accordingly the detection can be performed.

As shown in FIG. 6D, the electrical terminals 36C of the electrical connection elements 36 may be bonded to an external electrical component 62 such as a printed circuit board (PCB). Electrical components 32 may be mounded on the external electrical component 62 in advance. After the electrical terminals 36C of the electrical connection elements 36 is bonded to the external electrical component 62, the electrical components 32 is disposed in the clearance region 30C, and the device integration of the electronic component device package 4 can be improved.

In some embodiments of the present disclosure, the electronic device package is a three-dimensional (3D) stacking electronic device package including a substrate and a plurality of electronic components stacked on the substrate. The 3D stacking electronic device package includes one or more suspended electrical elements that do not overlap a joint region between a high-density electronic component and the substrate, and thus a molding condition in the joint region where mold voids tend to occur can be detected. Accordingly, the reliability of 3D stacking structure can be improved.

In the description of some embodiments, a component provided or disposed “on” or “over” another component can encompass cases where the former component is directly on (e.g., in physical or direct contact with) the latter component, as well as cases where one or more intervening components are located between the former component and the latter component.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

As used herein, the terms “approximately,” “substantially,” “substantial,” “around” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device package, comprising:
a substrate including a first surface, wherein the first surface comprises a plurality of electrical terminals including a first region and a second region, and a pitch of the electrical terminals of the first region is smaller than a pitch of the electrical terminals of the second region;
at least one first electronic component electrically connected to the substrate and at least over the first region; and
at least one electrical element disposed above the first electronic component and farther from the substrate than the first electronic component, wherein a number of the at least one electrical element under the first region is less than a number of the at least one electrical element under the second region.

2. The electronic device package according to claim 1, wherein the at least one electrical element includes a plurality of input/output (I/O) terminals away from the first electronic component.

3. The electronic device package according to claim 1, further comprising a second electronic component over the second region, the first electronic component further includes a plurality of conductive structures electrically connected to the electrical terminals of the first region, and the second electronic component further includes a plurality of conductive structures electrically connected to the electrical terminals of the second region.

4. The electronic device package according to claim 3, wherein the at least one electrical element is without overlapping the first electronic component in a direction substantially perpendicular to the first surface and under the first surface, and overlaps the second electronic component in the direction.

5. The electronic device package according to claim 1, wherein the first electronic component is further disposed over the second region, and the first electronic component further comprises a plurality of first conductive structures electrically connected to the electrical terminals of the first region, and a plurality of second conductive structures electrically connected to the electrical terminals of the second region.

6. The electronic device package according to claim 1, wherein the second region is free of electrical terminal.

7. The electronic device package according to claim 6, wherein the first electronic component is disposed over the first region, and the first electronic component further comprises a plurality of conductive structures electrically connected to the electrical terminals of the first region.

8. The electronic device package according to claim 2, further comprising a first encapsulation layer cover the first region and the second region and encapsulating the first electronic component and the at least one electrical element, wherein the I/O terminals of the electrical element are exposed from the first encapsulation layer to electrically connect to an external electrical component.

9. The electronic device package according to claim 8, wherein a surface of the first encapsulation layer and a surface of the at least one electrical element are substantially coplanar.

10. The electronic device package according to claim 9, wherein the first encapsulation layer includes a clearance region under the first region.

11. The electronic device package according to claim 8, further comprising a plurality of electrical connection elements electrically connected to the substrate, and extending through the first encapsulation layer to electrically connect to an external electrical component.

12. The electronic device package according to claim 11, further comprising at least one third electronic component disposed over a second surface of the substrate, and electrically connected to the substrate.

13. The electronic device package according to claim 12, further comprising a second encapsulation layer over the second surface of the substrate, and encapsulating the at least one third electronic component.

14. An electronic device package, comprising:
a substrate including a first surface, wherein the first surface comprises a plurality of electrical terminals including a first region and a second region, and a pitch of the electrical terminals of the first region is smaller than a pitch of the electrical terminals of the second region;
at least one first electronic component electrically connected to the substrate and at least over the first region; and
at least one electrical element disposed above the first electronic component and farther from the substrate than the first electronic component, wherein an area of the at least one electrical element under the first region projected on the first surface in a direction substantially perpendicular to the first surface is less than an area of the at least one electrical element under the second region projected on the first surface in the direction.

15. The electronic device package according to claim 14, wherein the at least one electrical element is without overlapping the first region in the direction.

16. The electronic device package according to claim 15, wherein a clearance region is defined to overlap the first region in the direction.

17. The electronic device package according to claim 14, further comprising an encapsulation layer over the first surface and encapsulating the first electronic component and the at least one electrical element, wherein the at least one electrical element includes a plurality of input/output (I/O) terminals exposed from the encapsulation layer.

18. The electronic device package according to claim 17, further comprising a plurality of electrical connection elements electrically connected to the substrate, and extending through the encapsulation layer to electrically connect to an external electrical component.

19. An electronic device package, comprising:
a substrate including a first surface, wherein the first surface comprises a plurality of electrical terminals including a first region and a second region, and a pitch of the electrical terminals of the first region is smaller than a pitch of the electrical terminals of the second region;
at least one first electronic component electrically connected to the substrate and at least over the first region; and
at least one electrical element disposed above the first electronic component and farther from the substrate than the first electronic component,
wherein a defect detectability in and/or under the first region is higher than a defect detectability in and/or under the second region.

20. The electronic device package according to claim 19, wherein the defect detectability comprises a void detectability.
